(19) United States
(12) Patent Application Publication
(10) Pub. No.: US 2026/0047431 A1
(43) Pub. Date: Feb. 12, 2026

(54) SEMICONDUCTOR PACKAGE

(71) Applicant: Samsung Electronics Co., Ltd., Suwon-si (KR)

(72) Inventors: Sangjin BAEK, Suwon-si (KR); Jihwang KIM, Suwon-si (KR); Kyungdon MUN, Suwon-si (KR)

(73) Assignee: Samsung Electronics Co., Ltd., Suwon-si (KR)

(21) Appl. No.: 19/051,363

(22) Filed: Feb. 12, 2025

(30) Foreign Application Priority Data
Aug. 12, 2024 (KR) 10-2024-0107881

(51) Int. Cl. H01L 23/367; H01L 21/48; H01L 21/56; H01L 23/00; H01L 23/498; H01L 23/538; H01L 25/16; H01L 25/18; H10B 80/00; H10D 80/30

(52) U.S. Cl. CPC H01L 23/3677; H01L 23/49838; H01L 23/5385; H01L 25/18; H10B 80/00; H10D 80/30; H01L 21/4853; H01L 21/565; H01L 24/16; H01L 24/32; H01L 24/73; H01L 25/16; H01L 2224/16145; H01L 2224/16227; H01L 2224/16238; H01L 2224/32145; H01L 2224/32245; H01L 2224/73204; H01L 2224/73253; H01L 2924/1815

(57) ABSTRACT

A semiconductor package includes a redistribution structure including a redistribution insulating layer and a redistribution pattern, a first semiconductor device mounted on the redistribution structure, vertical connection conductors on the redistribution structure and apart from the first semiconductor device in a horizontal direction, a second semiconductor device mounted on the vertical connection conductors, and a heat-dissipation plate mounted on the first semiconductor device, wherein the heat-dissipation plate includes a main body and a plurality of protrusions protruding from the main body in the horizontal direction.

### CROSS-REFERENCE TO RELATED APPLICATION

This application is based on and claims priority under 35 U.S.C. § 119 to Korean Patent Application No. 10-2024-0107881, filed on Aug. 12, 2024, in the Korean Intellectual Property Office, the disclosure of which is incorporated by reference herein in its entirety.

### BACKGROUND

The present disclosure relates to semiconductor packages.

With the rapid development of the electronics industry and the demands of users, electronic devices are gradually becoming smaller, more multifunctional, and larger in capacity. Accordingly, a semiconductor package including a plurality of semiconductor chips is desired. For example, a method of mounting several types of semiconductor chips side by side on a single package substrate or stacking semiconductor chips and/or packages on a single package substrate may be used.

### SUMMARY

Some example embodiments of the inventive concept provide semiconductor packages including a plurality of semiconductor devices.

According to an example embodiment of the inventive concepts, a semiconductor package includes a redistribution structure including a redistribution insulating layer and a redistribution pattern, a first semiconductor device on the redistribution structure, vertical connection conductors on the redistribution structure and apart from the first semiconductor device in a horizontal direction, a second semiconductor device on the vertical connection conductors, and a heat-dissipation plate on the first semiconductor device, wherein the heat-dissipation plate includes a main body and a plurality of protrusions protruding from the main body in the horizontal direction.

According to an example embodiment of the inventive concepts, a semiconductor package includes a first redistribution structure including a first redistribution insulating layer and a first redistribution pattern, a first semiconductor device on the first redistribution structure, a molding layer surrounding the first semiconductor device on the first redistribution structure, a second redistribution structure on the molding layer and the first semiconductor device, the second redistribution structure including a second redistribution insulating layer and a second redistribution pattern, vertical connection conductors in the molding layer, the vertical connection conductors being apart from the first semiconductor device in a horizontal direction, the vertical connection conductors between the first redistribution structure and the second redistribution structure, a second semiconductor device on the second redistribution structure, and a heat-dissipation plate apart from the second semiconductor device, the heat-dissipation being on the second redistribution structure, wherein the heat-dissipation plate includes a main body and a plurality of protrusions protruding from the main body in the horizontal direction.

According to an example embodiment of the inventive concepts, a semiconductor package includes a first redistribution structure including a first redistribution insulating layer and a first redistribution pattern, a first semiconductor device on the first redistribution structure, a molding layer surrounding the first semiconductor device on the first redistribution structure, a second redistribution structure on the molding layer and the first semiconductor device, the second redistribution structure including a second redistribution insulating layer and a second redistribution pattern, vertical connection conductors in the molding layer, the vertical connection conductors being apart from the first semiconductor device in a horizontal direction, the vertical connection conductors being between the first redistribution structure and the second redistribution structure, a second semiconductor device on the second redistribution structure, and a heat-dissipation plate apart from the second semiconductor device, the heat-dissipation plate being mounted on the second redistribution structure, wherein the first redistribution pattern includes a first conductive layer and a first via pattern, the second redistribution pattern includes a second conductive layer and a second via pattern, the heat-dissipation plate includes a main body and a plurality of protrusions protruding from the main body in the horizontal direction, a first side of the main body and one side of a first protrusion form a straight line in one horizontal direction, and a second side of the main body and one side of a second protrusion form a straight line in the one horizontal direction.

### BRIEF DESCRIPTION OF THE DRAWINGS

Example embodiments will be more clearly understood from the following detailed description taken in conjunction with the accompanying drawings in which:

FIG. 1 is a layout diagram of a semiconductor package according to an example embodiment;

FIG. 2 is a cross-sectional view taken along line A-A′ of FIG. 1;

FIG. 3 is a cross-sectional view taken along line B-B′ of FIG. 1;

FIG. 4 is a layout diagram of a semiconductor package according to an example embodiment;

FIG. 5 is a cross-sectional view taken along line C-C′ of FIG. 4;

FIG. 6 is a cross-sectional view of a semiconductor package according to an example embodiment;

FIG. 7 is a cross-sectional view of a semiconductor package according to an example embodiment;

FIG. 8 is a cross-sectional view of a semiconductor package according to an example embodiment;

FIG. example

FIGS. 10 to 17 are cross-sectional views of a method of manufacturing a semiconductor package, according to an example embodiment.

### DETAILED DESCRIPTION

Hereinafter, some example embodiments will be described in detail with reference to the accompanying drawings. The same reference numerals are used to denote the same elements in the drawings, and repeated descriptions thereof will be omitted. In the drawings below, the thickness or size of each layer may be exaggerated for clarity, and thus may differ to some extent from actual shape and proportion.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

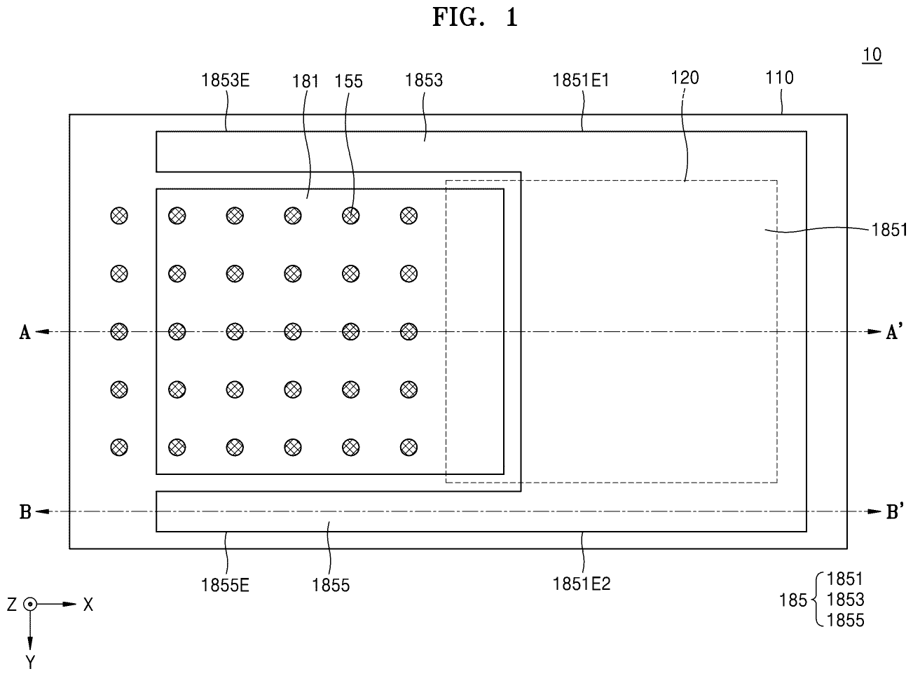

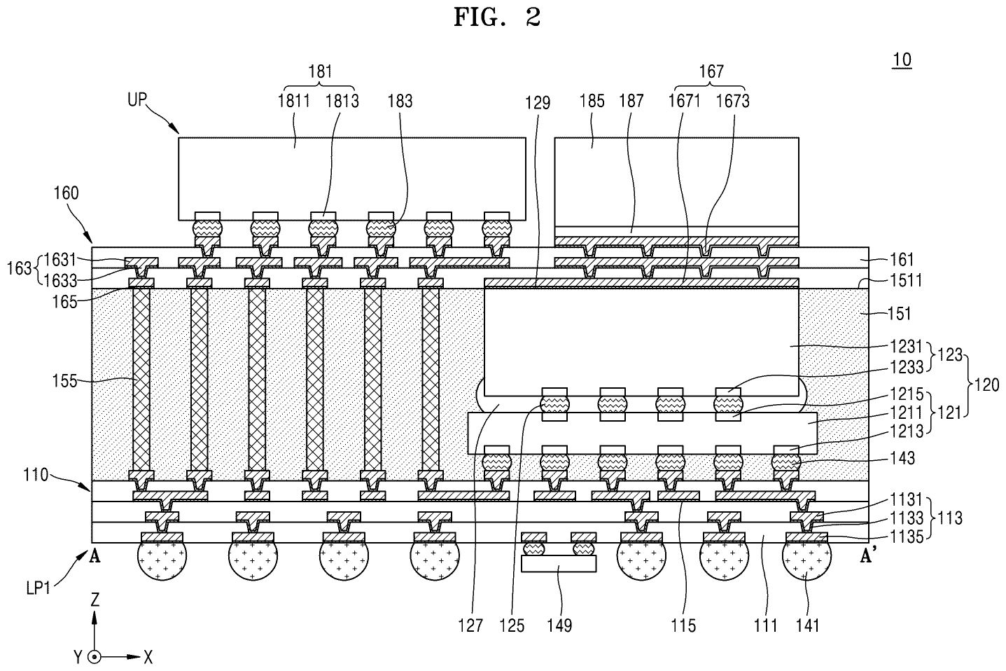

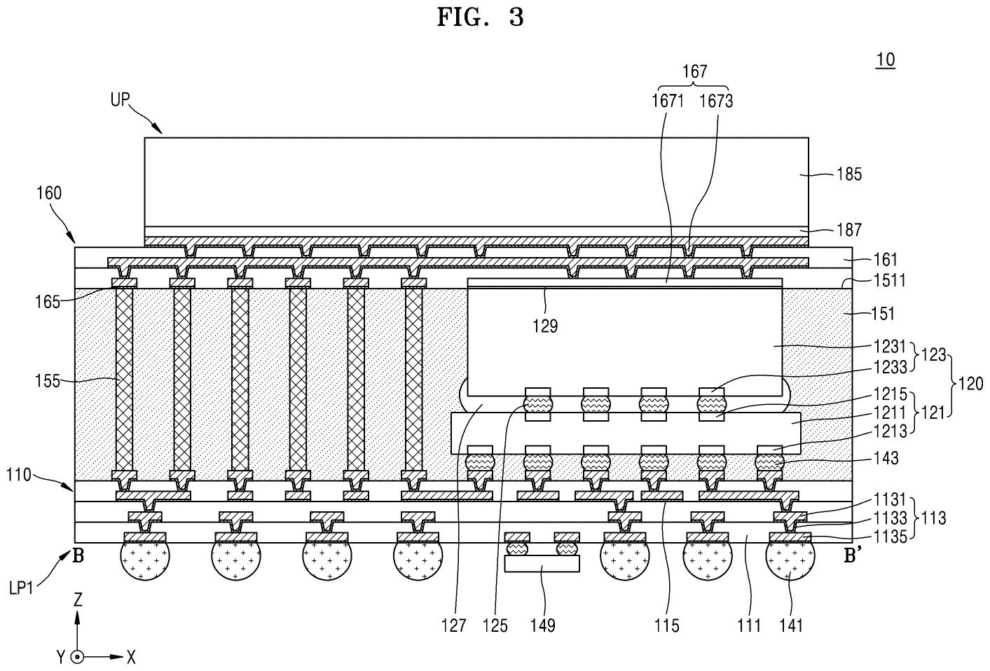

FIG. 1 is a layout diagram of a semiconductor package 10 according to an example embodiment. FIG. 2 is a cross-sectional view taken along line A-A′ of FIG. 1. FIG. 3 is a cross-sectional view taken along line B-B′ of FIG. 1.

Referring to FIGS. 1 to 3, the semiconductor package 10 may include a lower package LP1 and an upper package UP. The semiconductor package 10 may be a Package-on-Package (PoP)-type package in which the upper package UP is stacked on or adhered onto the lower package LP1.

The lower package LP1 may include a first redistribution structure 110, a first lower semiconductor device 120, a molding layer 151, vertical connection conductors 155, and a second redistribution structure 160. The lower package LP1 may be a fan-out package. A footprint of the first redistribution structure 110 may be greater than a footprint of the first lower semiconductor device 120. The footprint of the first redistribution structure 110 may be the same as the footprint of the semiconductor package 10.

The first redistribution structure 110 may be a package substrate for mounting a mounting component, such as the first lower semiconductor device 120, thereon. The first redistribution structure 110 may generally have a flat plate form or a panel form. The first redistribution structure 110 may include a top surface and a bottom surface that are opposite to each other, and each of the top surface and the bottom surface of the first redistribution structure 110 may be a planar surface. Hereinafter, a horizontal direction (e.g., X direction and/or Y direction) may be defined as a direction parallel to the top surface or the bottom surface of the first redistribution structure 110, and a vertical direction (Z direction) may be defined as a direction perpendicular to the top surface or the bottom surface of the first redistribution structure 110. A lateral width may be defined as a length obtained in the horizontal direction (e.g., X direction and/or Y direction).

The first redistribution structure 110 may include a plurality of first redistribution insulating layers 111 and a first conductive redistribution pattern 113.

The plurality of first redistribution insulating layers 111 may be stacked on each other in the vertical direction (Z direction). The plurality of first redistribution insulating layers 111 may include an insulating polymer, an epoxy, or a combination thereof. For example, each of the plurality of first redistribution insulating layers 111 may include photo imageable dielectric (PID) or photosensitive polyimide (PSPI).

The first conductive redistribution pattern 113 may include first conductive layers 1131, first conductive via patterns 1133, and external connection pads 1135. The first conductive layers 1131 may each extend in the horizontal direction (e.g., X direction and/or Y direction) and be at different vertical levels to form a multilayered structure. Each of the first conductive layers 1131 may be on any one of a top surface or a bottom surface of a corresponding one of the plurality of first redistribution insulating layers 111. For example, each of the first conductive layers 1131 may include line patterns extending as a line type along any one of the top surface or the bottom surface of the corresponding one of the plurality of first redistribution insulating layers 111. The first conductive layer 1131 provided on an uppermost one of the plurality of first redistribution insulating layers 111 may include pads to which first chip connection bumps 143 are adhered, respectively, and pads to which the vertical connection conductors 155 are adhered, respectively. The first conductive via patterns 1133 may pass through at least one of the plurality of first redistribution insulating layers 111 and extend in the vertical direction (Z direction). The first conductive via patterns 1133 may electrically connect the first conductive layers 1131 located at different vertical levels to each other or electrically connect the first conductive layer 1131 to the external connection pad 1135. The external connection pads 1135 may be at the bottom surface of the first redistribution structure 110 and contact external connection terminals 141, respectively. The external connection pads 1135 may be electrically connected to the first lower semiconductor device 120 and/or the vertical connection conductors 155 through the first conductive redistribution pattern 113. In an example embodiment, when viewed in cross-section, the external connection pads 1135 may have a rectangular shape.

For example, the first conductive redistribution pattern 113 may include metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof.

At least some of a plurality of first conductive layers 1131 may be integrally formed with some of a plurality of first conductive via patterns 1133. For example, some of the plurality of first conductive layers 1131 may be integrally formed with corresponding ones of the first conductive via patterns 1133, which are in contact with lower side surfaces of the some first conductive layers 1131. For example, the first conductive layer 1131 and the plurality of first conductive via patterns 1133 that are connected to each other may be formed together using an electroplating process.

In an example embodiment, each of the plurality of first conductive via patterns 1133 may have a tapered shape in which a lateral width of each of the first conductive via patterns 1133 reduces and extends in a direction from an upper side to a lower side thereof. In other words, the lateral width of each of the plurality of first conductive via patterns 1133 may gradually increase toward a top surface of the external connection pad 1135.

A seed metal layer 115 may be formed on a surface of the first conductive layer 1131 and a surface of the plurality of first conductive via patterns 1133. For example, the seed metal layer 115 may be located between a bottom surface of the first conductive layer 1131 and the first redistribution insulating layer 111 and located between each of a sidewall and a bottom surface of each of the plurality of first conductive via patterns 1133 and the first redistribution insulating layer 111. In addition, the seed metal layer 115 may be between the plurality of first conductive via patterns 1133 and the external connection pad 1135. Furthermore, the seed metal layer 115 may be between the external connection pad 1135 and the external connection terminal 141 and extend along a bottom surface of the external connection pad 1135. For example, the seed metal layer 115 may include at least one of copper (Cu), titanium (Ti), titanium tungsten (TiW), titanium nitride (TiN), tantalum (Ta), tantalum nitride (TaN), chromium (Cr), or aluminum (Al). For example, the seed metal layer 115 may be formed by using a physical vapor deposition (PVD) process, such as a sputtering process.

In an example embodiment, the external connection pad 1135 may have a rectangular shape when viewed in cross-section. In an example embodiment, the bottom surface of the external connection pad 1135 may be coplanar with the bottom surface of the first redistribution insulating layer 111. For example, the external connection pad 1135 may be formed using an electroplating process. In an example embodiment, the external connection pad 1135 may include a plurality of metal layers stacked in the vertical direction (Z direction).

External connection terminals 141 may be adhered to the external connection pads 1135 of the first redistribution structure 110, respectively. The external connection terminals 141 may be configured to electrically and physically connect the first redistribution structure 110 to an external device. The external connection terminals 141 may be formed from, for example, solder balls or solder bumps.

At least one passive component 149 may be adhered to a lower side of the first redistribution structure 110. The passive component 149 may be adhered to the lower side of the first redistribution structure 110 through solder bumps.

The first lower semiconductor device 120 may be mounted on the first redistribution structure 110. The first lower semiconductor device 120 may be electrically and physically connected to the first conductive redistribution pattern 113 of the first redistribution structure 110 through the first chip connection bumps 143. Each of the first chip connection bumps 143 may be located between the first lower semiconductor device 120 and the first conductive layer 1131 provided on the uppermost one of the first redistribution insulating layers 111. The first chip connection bumps 143 may each include a solder bump.

In an example embodiment, the first lower semiconductor device 120 may have a three-dimensional (3D) stack structure including a plurality of semiconductor chips stacked on each other in the vertical direction (Z direction). For example, the first lower semiconductor device 120 may include a lower semiconductor chip 121 and an upper semiconductor chip 123 on the lower semiconductor chip 121. The lower semiconductor chip 121 may include a lower semiconductor substrate 1211, lower connection pads 1213, which are provided at a lower side of the lower semiconductor substrate 1211 and in contact with the first chip connection bumps 143, and upper connection pads 1215 provided at an upper side of the lower semiconductor substrate 1211. In an example embodiment, the lower semiconductor chip 121 may further include through electrodes, which pass through the lower semiconductor substrate 1211 and electrically connect the lower connection pads 1213 to the upper connection pads 1215. The upper semiconductor chip 123 may include an upper semiconductor substrate 1231 and lower connection pads 1233 provided at a lower side of the upper semiconductor substrate 1231. The upper connection pads 1215 of the lower semiconductor chip 121 may be electrically and physically connected to the lower connection pads 1233 of the upper semiconductor chip 123 through inter-chip connection bumps 125. A gap-fill insulating layer 127 surrounding sidewalls of the inter-chip connection bumps 125 may be between the lower semiconductor chip 121 and the upper semiconductor chip 123. The gap-fill insulating layer 127 may include, for example, a non-conductive film (NCF).

The lower semiconductor substrate 1211 and the upper semiconductor substrate 1231 may include a semiconductor wafer. The lower semiconductor substrate 1211 and the upper semiconductor substrate 1231 may include, for example, silicon (Si). In some example embodiments, the lower semiconductor substrate 1211 and the upper semiconductor substrate 1231 may include a semiconductor element such as germanium (Ge), or a compound semiconductor such as silicon carbide (SiC), gallium arsenide (GaAs), InAs (indium arsenide (InAs), and indium phosphide (InP). The lower semiconductor substrate 1211 and the upper semiconductor substrate 1231 may include conductive regions, for example, doped wells or doped structures. The lower semiconductor chip 121 may include a semiconductor device layer provided in and/or on an active surface of the lower semiconductor substrate 1211 (e.g., a bottom surface of the lower semiconductor substrate 1211), and the upper semiconductor chip 123 may include a semiconductor device layer provided in and/or an active surface of the upper semiconductor substrate 1231 (e.g., a bottom surface of the upper semiconductor substrate 1231). Each of the semiconductor device layer of the lower semiconductor chip 121 and the semiconductor device layer of the upper semiconductor chip 123 may include individual devices. The individual devices may include, for example, a transistor. The individual devices may include microelectronic devices, for example, metal-oxide-semiconductor field effect transistors (MOSFETs), system large-scale integration (LSI), image sensors (e.g., a complementary metal-insulator-semiconductor (CMOS) imaging sensor (CIS)), a micro-electro-mechanical system (MEMS), active devices, and/or passive devices.

In an example embodiment, the first lower semiconductor device 120 may include at least three semiconductor chips stacked in the vertical direction (Z direction) or include a single semiconductor chip.

The molding layer 151 may be on the first redistribution structure 110. The molding layer 151 may cover at least a portion of the first lower semiconductor device 120 and the top surface of the first redistribution structure 110. The molding layer 151 may extend along a sidewall of the first lower semiconductor device 120 and surround the sidewall of the first lower semiconductor device 120. The molding layer 151 may not cover a top surface 129 of the first lower semiconductor device 120. The top surface 129 of the first lower semiconductor device 120 may be a top surface of the upper semiconductor chip 123. In an example embodiment, a top surface 1511 of the molding layer 151 may be coplanar with the top surface 129 of the first lower semiconductor device 120. Furthermore, the molding layer 151 may fill a gap between the first lower semiconductor device 120 and the first redistribution structure 110 and surround sidewalls of the first chip connection bumps 143. In still another example embodiment, the molding layer 151 may cover the top surface 129 of the first lower semiconductor device 120.

For example, the molding layer 151 may include an epoxy-based molding resin or a polyimide-based molding resin. For example, the molding layer 151 may include an epoxy molding compound (EMC).

The vertical connection conductors 155 may be apart from the first lower semiconductor device 120 in the horizontal direction (X direction and/or Y direction) and mounted on the first redistribution structure 110. The vertical connection conductors 155 may be between the first redistribution structure 110 and the second redistribution structure 160. The vertical connection conductors 155 may be configured to electrically connect the first conductive redistribution pattern 113 of the first redistribution structure 110 to the second conductive redistribution pattern 163 of the second redistribution structure 160. The vertical connection conductors 155 may pass through the molding layer 151 in the vertical direction (Z direction). A lower portion of each of the vertical connection conductors 155 may be in direct contact with the first conductive layer 1131 provided on the uppermost one of the first redistribution insulating layer 111, and an upper portion of each of the vertical connection conductors 155 may be in direct contact with the second conductive redistribution pattern 163. In an example embodiment, the top surfaces of the vertical connection conductors 155 may be coplanar with the top surface 1511 of the molding layer 151. The vertical connection conductors 155 may include, for example, copper (Cu).

The second redistribution structure 160 may be located on the molding layer 151 and the first lower semiconductor device 120. The second redistribution structure 160 may cover at least a portion of the top surface 1511 of the molding layer 151 and cover at least a portion of the top surface 129 of the first lower semiconductor device 120. In an example embodiment, a footprint of the second redistribution structure 160 may be the same as a footprint of the first redistribution structure 110. In an example embodiment, one sidewall of the second redistribution structure 160 may be aligned with a corresponding one of sidewalls of the molding layer 151 and a corresponding one of sidewalls of the first redistribution structure 110 in the vertical direction (Z direction).

The second redistribution structure 160 may include a plurality of second redistribution insulating layers 161, a second conductive redistribution pattern 163, and a third conductive redistribution pattern 167.

The plurality of second redistribution insulating layers 161 may be stacked on each other in the vertical direction (Z direction). The plurality of second redistribution insulating layers 161 may include an insulating polymer, an epoxy, or a combination thereof. For example, each of the plurality of second redistribution insulating layers 161 may include PID or PSPI.

The second conductive redistribution pattern 163 may include second conductive layers 1631 and second conductive via patterns 1633. The second conductive layers 1631 may be on any one surface of a top surface or a bottom surface of any one of the plurality of second redistribution insulating layers 161. The second conductive layers 1631 may be at different vertical levels and form a multilayered structure. For example, the second conductive layers 1631 may include line patterns extending as a line type along the top surface or the bottom surface of any one of the plurality of second redistribution insulating layers 161. The second conductive layer 1631 provided on an uppermost one of the plurality of second redistribution insulating layers 161 may include pads to which connection terminals 183 are adhered, respectively. A lowermost ones of the plurality of second conductive redistribution patterns 163 may include pads adhered to the vertical connection conductors 155, respectively. The second conductive via patterns 1633 may pass through at least one of the plurality of second redistribution insulating layers 161 and extend in the vertical direction (Z direction). The second conductive via patterns 1633 may electrically connect the second conductive layers 1631 located at different vertical levels to each other or electrically connect the second conductive layer 1631 to the vertical connection conductor 155. For example, the second conductive redistribution pattern 163 may include metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof.

At least some of a plurality of second conductive layers 1631 may be integrally formed with some of a plurality of second conductive via patterns 1633. For instance, some of the plurality of second conductive layers 1631 may be integrally formed with corresponding ones of the second conductive via patterns 1633, which are in contact with lower side surfaces of the some second conductive layers 1631. For example, the second conductive layer 1631 and the second conductive via pattern 1633 that are connected to each other may be formed together by using an electroplating process. A seed metal layer 165 may be on a surface of the second conductive layer 1631 and a surface of the second conductive via pattern 1633. For example, the seed metal layer 165 may be located between a bottom surface of the second conductive layer 1631 and the second redistribution insulating layer 161 and located between each of a sidewall and a bottom surface of the second conductive via pattern 1633 and the second redistribution insulating layer 161. For example, the seed metal layer 165 may include at least one of copper (Cu), titanium (Ti), titanium tungsten (TiW), titanium nitride (TiN), tantalum (Ta), tantalum nitride (TaN), chromium (Cr), or aluminum (Al).

In an example embodiment, each of the plurality of second conductive via patterns 1633 may have a tapered shape in which a lateral width of each of the second conductive via patterns 1633 reduces and extends in a direction from an upper side to a lower side thereof. In other words, the lateral width of each of the plurality of second conductive via patterns 1633 may gradually increase toward the top surface 1511 of the molding layer 151 or a top surface of the vertical connection conductor 155.

The third conductive redistribution pattern 167 may include a third conductive layers 1671 and a third conductive via patterns 1673. The third conductive layers 1671 may be located on any one surface of the top surface or the bottom surface of any one of the plurality of second redistribution insulating layers 161. The third conductive layers 1671 may be at different vertical levels and form a multilayered structure. For example, the third conductive layers 1671 may have a plate form that is generally parallel to the top surface 129 of the first lower semiconductor device 120.

Each of the third conductive layers 1671 may be at the same vertical level as a corresponding one of the second conductive layers 1631. Each of the third conductive layers 1671 may substantially have the same thickness as a corresponding one of the second conductive layers 1631, which is at the same vertical level. A lowermost one of the third conductive layers 1671 may extend along the top surface 129 of the first lower semiconductor device 120 and contact the top surface 129 of the first lower semiconductor device 120. In an example embodiment, the lowermost one of the third conductive layers 1671 may entirely cover the top surface 129 of the first lower semiconductor device 120. The third conductive via patterns 1673 may pass through at least one of the plurality of second redistribution insulating layers 161 and extend in the vertical direction (Z direction). The third conductive via patterns 1673 may connect the third conductive layers 1671 located at different vertical levels to each other. A seed metal layer 165 may be on a surface of the third conductive layers 1671 and a surface of the third conductive via patterns 1673. For example, the seed metal layer 165 may extend along a bottom surface of the third conductive layers 1671 or extend along a sidewall and a bottom surface of the third conductive via patterns 1673. In an example embodiment, the third conductive redistribution pattern 167 may be formed together with the second conductive redistribution pattern 163 of the second redistribution structure 160 by using the same metal wiring process. In this case, a material and/or material composition of the third conductive redistribution pattern 167 may substantially be the same as a material and/or material composition of the second conductive redistribution pattern 163.

The upper package UP may be on the second redistribution structure 160. The upper package UP may include at least one upper semiconductor device 181 on the second redistribution structure 160. The at least one upper semiconductor device 181 may include a semiconductor chip and/or a package including a semiconductor chip. For example, the upper semiconductor device 181 may include a semiconductor substrate 1811 and chip pads 1813. The chip pads 1813 of the upper semiconductor device 181 may be electrically and physically connected to the second conductive redistribution pattern 163 of the second redistribution structure 160 through the connection terminals 183.

In an example embodiment, the first lower semiconductor device 120 and the upper semiconductor device 181 may include different kinds of semiconductor chips and be electrically connected to each other through the first conductive redistribution pattern 113 of the first redistribution structure 110, the vertical connection conductors 155, and the second conductive redistribution pattern 163 of the second redistribution structure 160. The first lower semiconductor device 120 and the upper semiconductor device 181 each may include a memory chip, a logic chip, a System-on-Chip (SoC), a power management integrated circuit (PMIC) chip, or a radio-frequency integrated circuit (RFIC) chip. The memory chip may include a dynamic random access memory (DRAM) chip, a static RAM (SRAM) chip, a magnetic RAM (MRAM) chip, a NAND flash memory chip, and/or a high-bandwidth memory (HBM) chip. The logic chip may include an application processor (AP), a micro-processor (MP), a central processing unit (CPU), a controller, and/or an application specific integrated circuit (ASIC). For example, the SoC may include at least two circuits among a logic circuit, a memory circuit, a digital IC, an RFIC, and an input/output (I/O) circuit.

A heat-dissipation plate 185 may overlap a portion of the first lower semiconductor device 120 in the vertical direction (Z direction) and be adhered onto the third conductive redistribution pattern 167. The heat-dissipation plate 185 may be apart from the upper semiconductor device 181 in the horizontal direction (X direction and/or Y direction) and overlap the upper semiconductor device 181 in the horizontal direction (X direction and/or Y direction). For example, at least 70% of the first lower semiconductor device 120 may overlap the heat-dissipation plate 185 in the vertical direction (Z direction).

The heat-dissipation plate 185 may be thermally coupled to the first lower semiconductor device 120 through the third conductive redistribution pattern 167. The heat-dissipation plate 185 may include a heat sink, a heat pipe, and/or a heat slug. Heat generated by the first lower semiconductor device 120 may be dissipated to the outside through the third conductive redistribution pattern 167 and the heat-dissipation plate 185. The heat-dissipation plate 185 may include a thermally conductive material having a relatively high thermal conductivity. A thermal conductivity of a material included in the heat-dissipation plate 185 may be higher than a thermal conductivity of silicon. In other words, a thermal resistance of the material included in the heat-dissipation plate 185 may be lower than a thermal resistance of silicon. For example, the heat-dissipation plate 185 may include metal such as copper (Cu) and aluminum (Al) or a carbon-containing material such as graphene, graphite, and/or carbon nanotubes.

When viewed in a horizontal cross-section (e.g., referring to the layout diagram of FIG. 1), the heat-dissipation plate 185 may have a U shape. The heat-dissipation plate 185 may include a main body 1851, a first protrusion 1853, and a second protrusion 1855. Each of the first protrusion 1853 and the second protrusion 1855 may extend from the main body 1851. Each of the first protrusion 1853 and the second protrusion 1855 may have a line shape, which has a length in an extension direction that is greater than a width in the horizontal direction.

The first protrusion 1853 and the second protrusion 1855 may extend in one horizontal direction (X direction and/or Y direction) from the main body 1851. Also, the first protrusion 1853 and the second protrusion 1855 may be apart from each other in the horizontal direction (X direction and/or Y direction), which is perpendicular to the extension direction. For example, the first protrusion 1853 and the second protrusion 1855 may extend in a first horizontal direction (X direction), and the first protrusion 1853 and the second protrusion 1855 may be apart from each other in a second horizontal direction (Y direction).

In an example embodiment, when viewed in a horizontal cross-section (e.g., referring to the layout diagram of FIG. 1), a first side 1851E1 of the main body 1851 may form a straight line with one side 1853E of the first protrusion 1853. Also, a second side 1851E2 of the main body 1851 may form a straight line with one side 1855E of the second protrusion 1855.

When viewed in a horizontal cross-section (e.g., referring to the layout diagram of FIG. 1), each of the main body 1851, the first protrusion 1853, and the second protrusion 1855 may have a rectangular shape. In an example embodiment, the main body 1851, the first protrusion 1853, and the second protrusion 1855 are only formal distinctions for explanation and may be integrally formed with each other. In still another example embodiment, at least two of the main body 1851, the first protrusion 1853, and the second protrusion 1855 may be formed separately.

When viewed in a horizontal cross-section (e.g., referring to the layout diagram of FIG. 1), the heat-dissipation plate 185 may have a U shape, and thus, the third conductive layers 1671 and/or a thermally conductive adhesive layer 187 each may also have a U shape. When viewed in a horizontal cross-section (e.g., referring to the layout diagram of FIG. 1), because the heat-dissipation plate 185 has the U shape, at least a portion of each of a plurality of sides of the upper semiconductor device 181 may face the heat-dissipation plate 185. In an example embodiment, when viewed in a horizontal cross-section (e.g., referring to the layout diagram of FIG. 1), the heat-dissipation plate 185 may surround the upper semiconductor device 181.

The heat-dissipation plate 185 may be adhered onto the first lower semiconductor device 120 through the thermally conductive adhesive layer 187. The thermally conductive adhesive layer 187 may include a thermally conductive and electrically insulating material. The thermally conductive adhesive layer 187 may include a thermal interface material, a polymer including metal powder, thermal grease, or a combination thereof.

In an example embodiment, a heat generation amount of the first lower semiconductor device 120 may be greater than a heat generation amount of the upper semiconductor device 181. In an example embodiment, the first lower semiconductor device 120 may include a logic chip and/or an SoC. According to an example embodiment, because the first lower semiconductor device 120 having a relatively large heat generation amount is thermally coupled to the heat-dissipation plate 185 through the third conductive redistribution pattern 167, heat-dissipation characteristics of the first lower semiconductor device 120 may improve. Also, performance of electronic components around the first lower semiconductor device 120 may be reduced or prevented from deteriorating due to heat generation of the first lower semiconductor device 120.

The upper semiconductor device 181 may overlap a portion of the first lower semiconductor device 120 in the vertical direction (Z direction). In an example embodiment, when viewed in cross-section, a portion of the upper semiconductor device 181 may overlap a first region of the first redistribution structure 110 on which the first lower semiconductor device 120 is mounted, in the vertical direction (Z direction), and another portion of the upper semiconductor device 181 may overlap a second region of the first redistribution structure 110 on which the vertical connection conductors 155 are located, in the vertical direction (Z direction).

In an example embodiment, when viewed in cross-section, a first portion of the first lower semiconductor device 120 may overlap the upper semiconductor device 181 in the vertical direction (Z direction), and a second portion of the first lower semiconductor device 120 may not overlap the upper semiconductor device 181 in the vertical direction (Z direction). The second portion of the first lower semiconductor device 120 may be another portion of the first lower semiconductor device 120 excluding the first portion of the first lower semiconductor device 120.

In the semiconductor package 10, a signal (e.g., a data signal, a control signal, a power signal and/or a ground signal) provided from an external device may be provided to the first lower semiconductor device 120 through a signal transmission path including the external connection terminal 141 and the first conductive redistribution pattern 113. The signal (e.g., the data signal, the control signal, the power signal and/or the ground signal) provided from the external device may be provided to the upper semiconductor device 181 through a signal transmission path including the external connection terminal 141, the first conductive redistribution pattern 113, the vertical connection conductor 155, and the second conductive redistribution pattern 163. Electrical signals may be transmitted between the first lower semiconductor device 120 and the upper semiconductor device 181 through the first conductive redistribution pattern 113, the vertical connection conductor 155, and the second conductive redistribution pattern 163.

According to an example embodiment, a portion of the first lower semiconductor device 120 may overlap the upper semiconductor device 181 in the vertical direction (Z direction), and another portion of the first lower semiconductor device 120 may be thermally coupled to the heat-dissipation plate 185. Thus, the semiconductor package 10 having improved heat-dissipation characteristics and/or a reduced or minimized footprint may be provided.

According to an example embodiment, because the heat-dissipation plate 185 has a U shape, an area of the heat-dissipation plate 185 may increase, and thus, heat-dissipation characteristics of the semiconductor package 10 may improve.

According to an example embodiment, because the heat-dissipation plate 185 has a U shape, the heat-dissipation plate 185 may have an asymmetrical structure along a direction perpendicular to an extension direction thereof and support the lower package LP1 more effectively, and thus, mechanical stability of the semiconductor package 10 may improve.

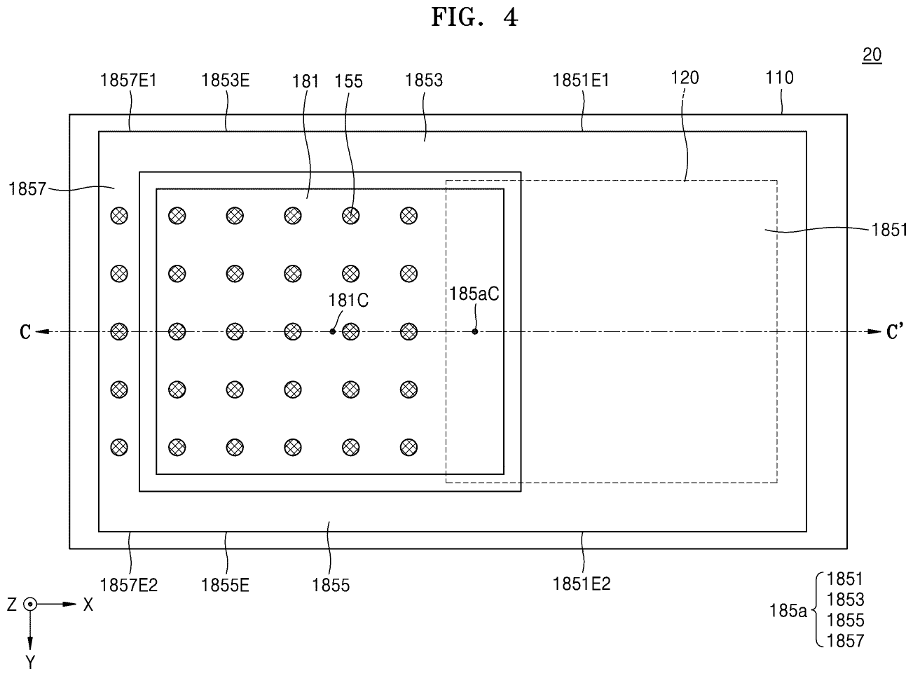

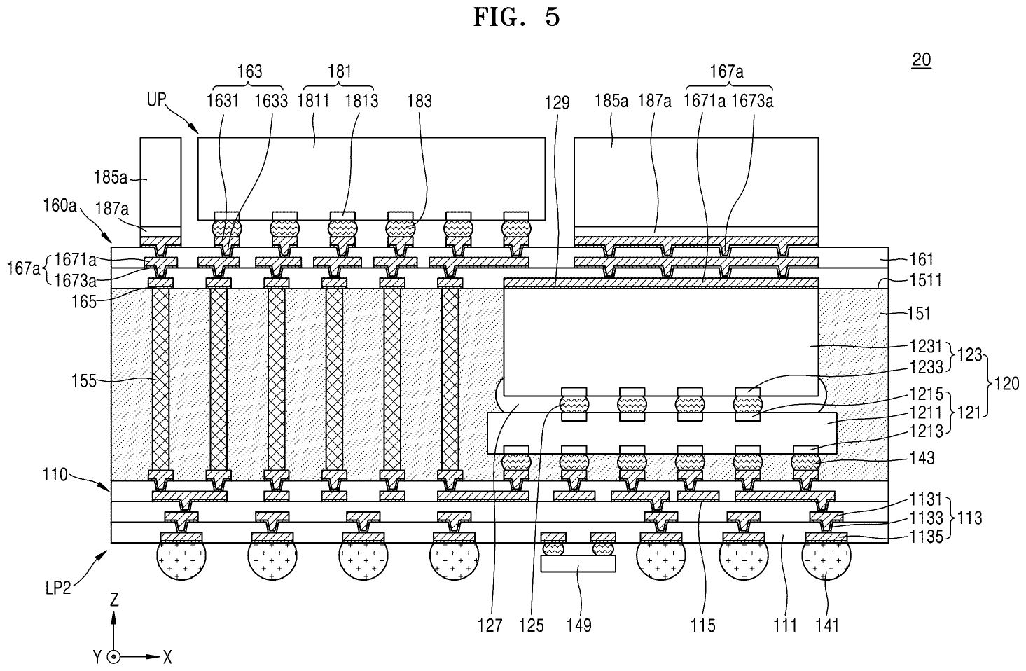

FIG. 4 is a layout diagram of a semiconductor package 20 according to an example embodiment. FIG. 5 is a cross-sectional view taken along line C-C′ of FIG. 4. FIGS. 4 and 5 are described with reference to FIGS. 1 to 3.

Referring to FIGS. 4 and 5, the semiconductor package 20 may include a lower package LP2, an upper package UP, and a heat-dissipation plate 185a. The lower package LP2 may include a first redistribution structure 110, a first lower semiconductor device 120, a molding layer 151, vertical connection conductors 155, and a second redistribution structure 160a. The first redistribution structure 110, the first lower semiconductor device 120, the molding layer 151, the vertical connection conductors 155, and the upper package UP of FIGS. 1 to 5 are substantially the same as the first redistribution structure 110, the first lower semiconductor device 120, the molding layer 151, the vertical connection conductors 155, and the upper package UP of FIGS. 4 and 5, respectively. Thus, the description below will now focus on the second redistribution structure 160a and the heat-dissipation plate 185a.

When viewed in a horizontal cross-section (e.g., referring to the layout diagram of FIG. 4), the heat-dissipation plate 185a may have a tetragonal ring shape. The tetragonal ring shape may have a rectangular shape and include a tetragonal hollow inside. A center 185aC of the heat-dissipation plate 185a may be apart from a center of the hollow in the horizontal direction (X direction and/or Y direction). When viewed in cross-section (e.g., referring to the layout diagram of FIG. 4), an upper semiconductor device 181 may be located in the hollow. That is, the center 185aC of the heat-dissipation plate 185a may be apart from a center 181C of the upper semiconductor device 181 in the horizontal direction (X direction and/or Y direction).

The heat-dissipation plate 185a may include a main body 1851, a first protrusion 1853, a second protrusion 1855, and a connection 1857. The main body 1851, the first protrusion 1853, and the second protrusion 1855 of the heat-dissipation plate 185a may be substantially the same as the main body 1851, the first protrusion 1853, and the second protrusion 1855 of the heat-dissipation plate 185, respectively.

The connection 1857 may connect the first protrusion 1853 to the second protrusion 1855. When viewed in a horizontal cross-section (e.g., referring to the layout diagram of FIG. 4), the connection 1857 may have a line shape. In an example embodiment, the connection 1857 may extend in a direction in which the first protrusion 1853 is apart from the second protrusion 1855. Also, the connection 1857 may be apart from the main body 1851 in a direction in which the first protrusion 1853 and the second protrusion 1855 extend. For example, the connection 1857 may be apart from the main body 1851 in a first horizontal direction (X direction) and extend in a second horizontal direction (Y direction).

One side of each of the first protrusion 1853 and the second protrusion 1855 may be in contact with the main body 1851, and another side of each of the first protrusion 1853 and the second protrusion 1855 may be in contact with the connection 1857.

In an example embodiment, when viewed in a horizontal cross-section (e.g., referring to the layout diagram of FIG. 4), a first side 1857E1 of the connection 1857 may form a straight line with one side 1853E of the first protrusion 1853. Also, the second side 1857E2 of the connection 1857 may form a straight line with one side 1855E of the second protrusion 1855.

In an example embodiment, the main body 1851, the first protrusion 1853, the second protrusion 1855, and the connection 1857 are only formal distinctions for explanation and may be integrally formed with each other. In still another example embodiment, at least two of the main body 1851, the first protrusion 1853, the second protrusion 1855, and the connection 1857 may be formed separately.

When viewed in a horizontal cross-section (e.g., referring to the layout diagram of FIG. 4), the heat-dissipation plate 185a may have the tetragonal ring shape. Thus, a third conductive layers 1671a) and/or a thermally conductive adhesive layer 187a may each also have a tetragonal ring shape. When viewed in a horizontal cross-section (e.g., referring to the layout diagram of FIG. 4), because the heat-dissipation plate 185a has the tetragonal ring shape, each of a plurality of sides of the upper semiconductor device 181 may face the heat-dissipation plate 185a. That is, when viewed in cross-section, the heat-dissipation plate 185a may surround the upper semiconductor device 181.

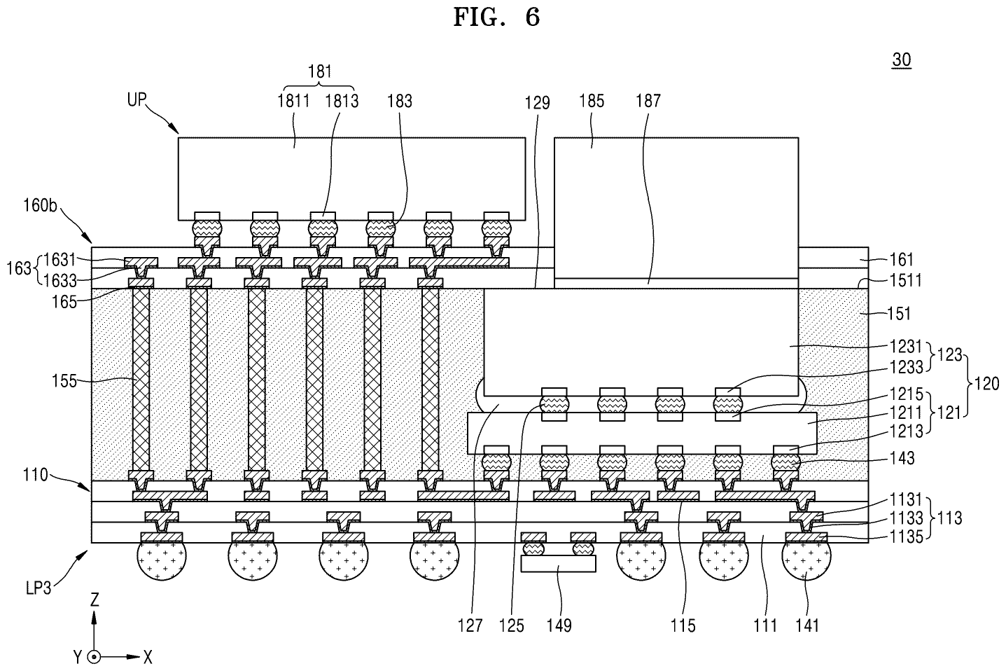

FIG. 6 is a cross-sectional view of a semiconductor package 30 according to an example embodiment. FIG. 6 is a cross-sectional view of a region corresponding to line A-A′ of FIG. 2. FIG. 6 is described with reference to FIGS. 1 to 5.

Referring to FIG. 6, the semiconductor package 30 may include a lower package LP3, an upper package UP, and a heat-dissipation plate 185. The lower package LP3 may include a first redistribution structure 110, a first lower semiconductor device 120, a molding layer 151, vertical connection conductors 155, and a second redistribution structure 160b. The first redistribution structure 110, the first lower semiconductor device 120, the molding layer 151, the vertical connection conductors 155, the upper package UP, and the heat-dissipation plate 185 of FIGS. 1 to 3 are substantially the same as the first redistribution structure 110, the first lower semiconductor device 120, the molding layer 151, the vertical connection conductors 155, the upper package UP, and the heat-dissipation plate 185 of FIG. 6, respectively. Thus, the description below will now focus on differences between the semiconductor package 10 of FIGS. 1 to 3 and the semiconductor package 30 of FIG. 6.

The second redistribution structure 160b may include a through hole passing through the second redistribution insulating layer 161, and the heat-dissipation plate 185 may be accommodated inside the through hole of the second redistribution insulating layer 161. The heat-dissipation plate 185 may be adhered to a portion of the top surface 129 of the first lower semiconductor device 120, which overlaps the through hole of the second redistribution insulating layer 161, through a thermally conductive adhesive layer 187.

The heat-dissipation plate 185 may be adhered to the top surface 129 of the first lower semiconductor device 120 by the thermally conductive adhesive layer 187. It is obvious that the heat-dissipation plate 185 may be replaced by the heat-dissipation plate 185a having the tetragonal ring shape of FIGS. 4 and 5.

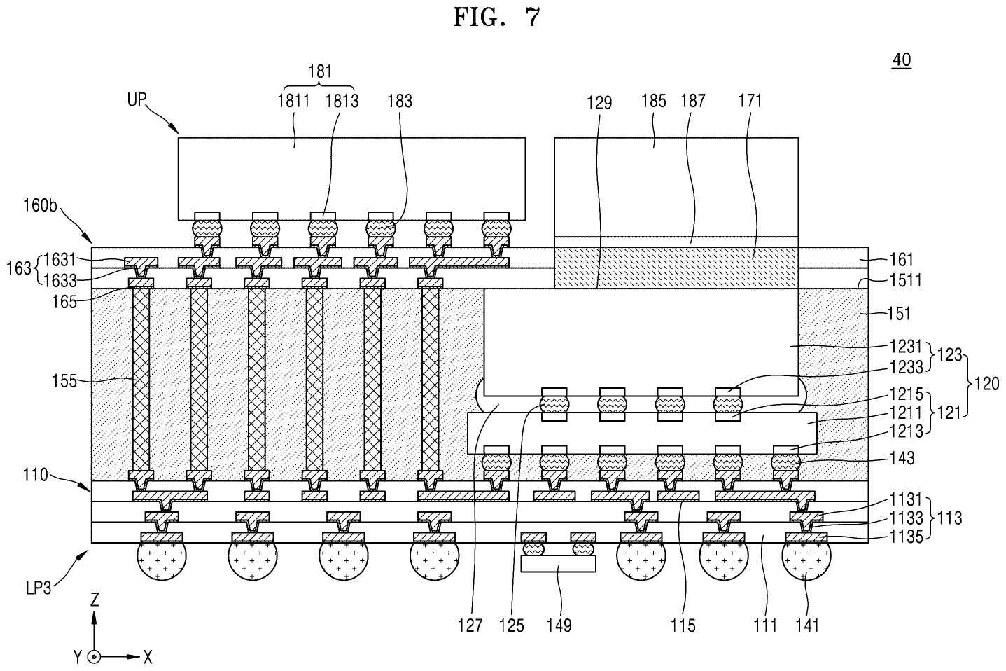

FIG. 7 is a cross-sectional view of a semiconductor package 40 according to an example embodiment. FIG. 7 is a cross-sectional view of a region corresponding to line A-A′ of FIG. 2. FIG. 7 is described with reference to FIGS. 1 to 6.

Referring to FIG. 7, the semiconductor package 40 may include a lower package LP3, an upper package UP, a heat-dissipation pad structure 171, and a heat-dissipation plate 185.

The heat-dissipation pad structure 171 may be in contact with a top surface 129 of a first lower semiconductor device 120. The heat-dissipation pad structure 171 may be thermally coupled to the first lower semiconductor device 120 and may not be electrically connected to the first lower semiconductor device 120, the second conductive redistribution pattern 163, and the vertical connection conductors 155. The heat-dissipation pad structure 171 may pass through a second redistribution insulating layer 161 of a second redistribution structure 160b in a vertical direction (Z direction) and directly contact the top surface 129 of the first lower semiconductor device 120. The heat-dissipation pad structure 171 may extend along a portion of the top surface 129 of the first lower semiconductor device 120 and cover the portion of the top surface 129 of the first lower semiconductor device 120. For example, a portion of the top surface 129 of the first lower semiconductor device 120 may be in direct contact with the heat-dissipation pad structure 171, and another portion of the top surface 129 of the first lower semiconductor device 120 may be in direct contact with the second redistribution insulating layer 161.

In an example embodiment, the heat-dissipation pad structure 171 may be inside of a through hole of the second redistribution insulating layer 161 of the second redistribution structure 160b and at least partially fill the through hole of the second redistribution insulating layer 161 of the second redistribution structure 160b. For example, the heat-dissipation pad structure 171 may entirely fill the through hole of the second redistribution insulating layer 161 and extend from the bottom surface of the second redistribution insulating layer 161 to the top surface thereof.

The heat-dissipation pad structure 171 may include a material (e.g., metal) having excellent or relatively high thermal conductivity. In an example embodiment, the heat-dissipation pad structure 171 may include at least one of copper (Cu) or aluminum (Al). The heat-dissipation pad structure 171 may transmit heat generated by the first lower semiconductor device 120 to the outside of the semiconductor package 40 and/or to the heat-dissipation plate 185. In an example embodiment, the heat-dissipation pad structure 171 may be formed together with the second conductive redistribution pattern 163 of the second redistribution structure 160b by using the same metal wiring process. In this case, a material and/or material composition of the heat-dissipation pad structure 171 may be substantially the same as a material and/or material composition of the second conductive redistribution pattern 163. In an example embodiment, the heat-dissipation pad structure 171 may be formed using a different process from the process of forming the second conductive redistribution pattern 163 of the second redistribution structure 160b. In an example embodiment, a material and/or material composition of the heat-dissipation pad structure 171 may be different from a material and/or material composition of the second conductive redistribution pattern 163.

The heat-dissipation plate 185 may overlap a portion of the first lower semiconductor device 120 in the vertical direction (Z direction) and be adhered onto the heat-dissipation pad structure 171. The heat-dissipation plate 185 may be apart from an upper semiconductor device 181 in the horizontal direction (X direction and/or Y direction) and overlap the upper semiconductor device 181 in the horizontal direction (X direction and/or Y direction). The heat-dissipation plate 185 may be thermally coupled to the first lower semiconductor device 120 through the heat-dissipation pad structure 171. Heat generated by the first lower semiconductor device 120 may be dissipated to the outside through the heat-dissipation pad structure 171 and the heat-dissipation plate 185.

It is obvious that the heat-dissipation plate 185 may be replaced by the heat-dissipation plate 185a having the tetragonal ring shape of FIGS. 4 and 5.

According to an example embodiment, because the first lower semiconductor device 120 having a relatively large heat generation amount is thermally coupled to the heat-dissipation plate 185 through the heat-dissipation pad structure 171, heat-dissipation characteristics of the first lower semiconductor device 120 may improve. Also, the performance of electronic components around the first lower semiconductor device 120 may be reduced or prevented from deteriorating due to heat generation of the first lower semiconductor device 120.

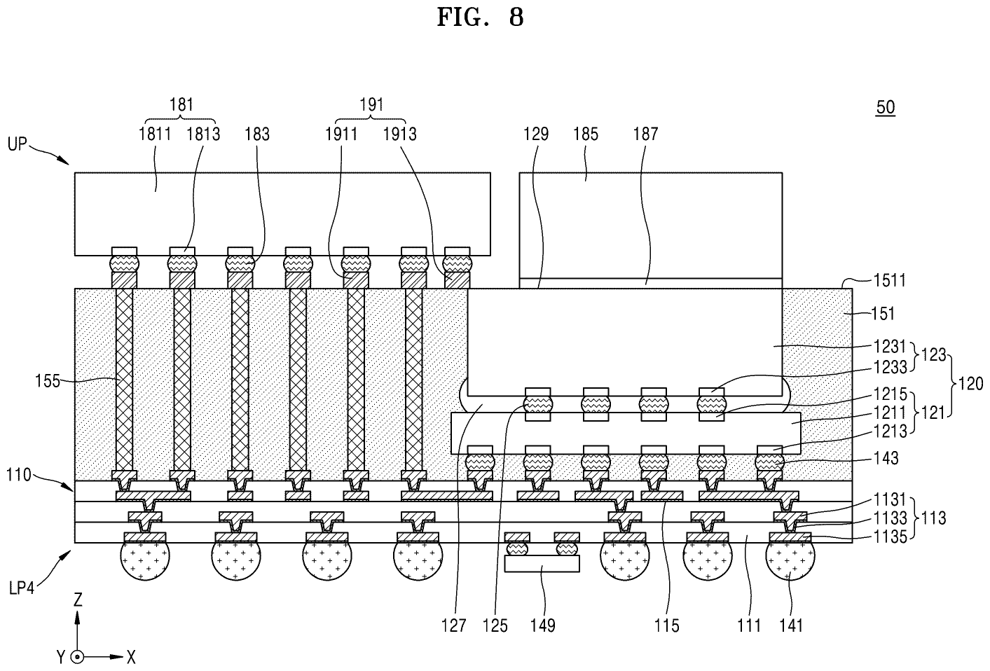

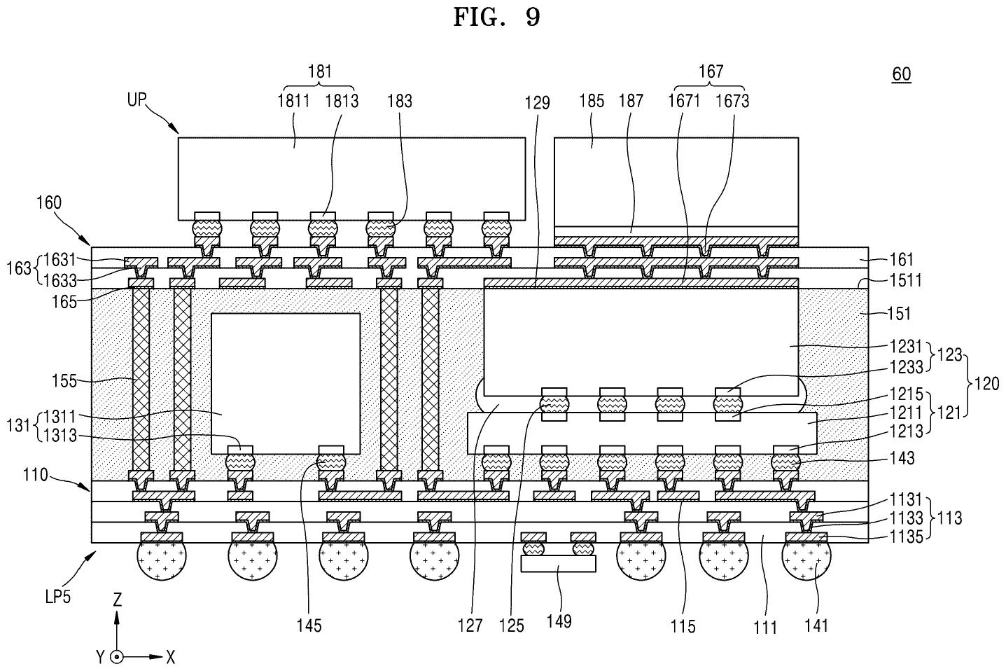

FIG. 8 is a cross-sectional view of a semiconductor package 50 according to an example embodiment. FIG. 8 is a cross-sectional view of a region corresponding to line A-A′ of FIG. 2. FIG. 8 is described with reference to FIGS. 1 to 5.

Referring to FIG. 8, the semiconductor package 50 may include a lower package LP4, an upper package UP, and a heat-dissipation plate 185. The lower package LP4 may include a first redistribution structure 110, a first lower semiconductor device 120, a molding layer 151, and vertical connection conductors 155. The first redistribution structure 110, the first lower semiconductor device 120, the molding layer 151, the vertical connection conductors 155, the upper package UP, and the heat-dissipation plate 185 of FIGS. 1 to 3 are substantially the same as the first redistribution structure 110, the first lower semiconductor device 120, the molding layer 151, the vertical connection conductors 155, the upper package UP, and the heat-dissipation plate 185 of FIG. 8, respectively. Thus, the description will now focus on differences between the semiconductor package 10 of FIGS. 1 to 3 and the semiconductor package 50 of FIG. 8.

The lower package LP4 may include a conductive layer 191 provided on a top surface 1511 of the molding layer 151. The conductive layer 191 may include conductive pads 1911 connected to top surfaces of the vertical connection conductors 155 and at least one dummy pad 1913 that is not connected to the vertical connection conductors 155. The at least one dummy pad 1913 may be on the top surface 1511 of the molding layer 151 and/or a top surface 129 of the first lower semiconductor device 120. A material included in the conductive layer 191 may be substantially the same as or similar to a material included in the first conductive layer 1131. An upper semiconductor device 181 of the upper package UP may be located on the conductive pads 1911 and the at least one dummy pad 1913 of the conductive layer 191 through the connection terminals 183. The upper semiconductor device 181 may be electrically and physically connected to the vertical connection conductors 155 through the conductive pads 1911 of the conductive layer 191. In the semiconductor package 50, the heat-dissipation plate 185 may be adhered to the top surface 129 of the first lower semiconductor device 120 by a thermally conductive adhesive layer 187.

It is obvious that the heat-dissipation plate 185 may be replaced by the heat-dissipation plate 185a having the tetragonal ring shape of FIGS. 4 and 5.

FIG. 9 is a cross-sectional view of a semiconductor package 60 according to an example embodiment. FIG. 9 is a cross-sectional view of a region corresponding to line A-A′ of FIG. 2. FIG. 9 is described with reference to FIGS. 1 to 5.

Referring to FIG. 9, the semiconductor package 60 may include a lower package LP5, an upper package UP, and a heat-dissipation plate 185. The lower package LP5 may include a first redistribution structure 110, a first lower semiconductor device 120, a second lower semiconductor device 131, a molding layer 151, vertical connection conductors 155, and a second redistribution structure 160. The first redistribution structure 110, the first lower semiconductor device 120, the molding layer 151, the vertical connection conductors 155, the second redistribution structure 160, the upper package UP, and the heat-dissipation plate 185 of FIGS. 1 to 3 are substantially the same as the first redistribution structure 110, the first lower semiconductor device 120, the molding layer 151, the vertical connection conductors 155, the second redistribution structure 160, the upper package UP, and the heat-dissipation plate 185 of FIG. 9, respectively. Thus, the description below will now focus on the second lower semiconductor device 131.

In an example embodiment, the second lower semiconductor device 131 may include any one of a memory chip, a logic chip, an SoC, a PMIC chip, or an RFIC chip. The second lower semiconductor device 131 may include a semiconductor substrate 1311 and chip pads 1313. The second lower semiconductor device 131 may be mounted in a flip-chip form on the first redistribution structure 110. In this case, a bottom surface of the semiconductor substrate 1311 may be an active surface of the semiconductor substrate 1311, and a top surface of the semiconductor substrate 1311 may be an inactive surface of the semiconductor substrate 1311. A semiconductor device layer of the second lower semiconductor device 131 may be located on the bottom surface of the semiconductor substrate 1311, and the chip pads 1313 may be provided on a bottom surface of the second lower semiconductor device 131. Second chip connection bumps 145 may be located between the chip pads 1313 of the second lower semiconductor device 131 and the first redistribution structure 110 and configured to electrically connect the chip pads 1313 of the second lower semiconductor device 131 to a first conductive redistribution pattern 113. The second lower semiconductor device 131 may be apart from the first lower semiconductor device 120 in a horizontal direction (X direction and/or Y direction) and overlap an upper semiconductor device 181 in a vertical direction (Z direction). The second lower semiconductor device 131 may be electrically connected to the first lower semiconductor device 120 through the first conductive redistribution pattern 113. The second lower semiconductor device 131 may be electrically connected to the upper semiconductor device 181 through the first conductive redistribution pattern 113, the vertical connection conductors 155, and the second conductive redistribution pattern 163.

In still another example embodiment, the second lower semiconductor device 131 may be mounted on the first redistribution structure 110 in a face-up manner. In yet another example embodiment, the second lower semiconductor device 131 may include a dummy chip.

It is obvious that the heat-dissipation plate 185 may be replaced by the heat-dissipation plate 185a having the tetragonal ring shape of FIGS. 4 and 5.

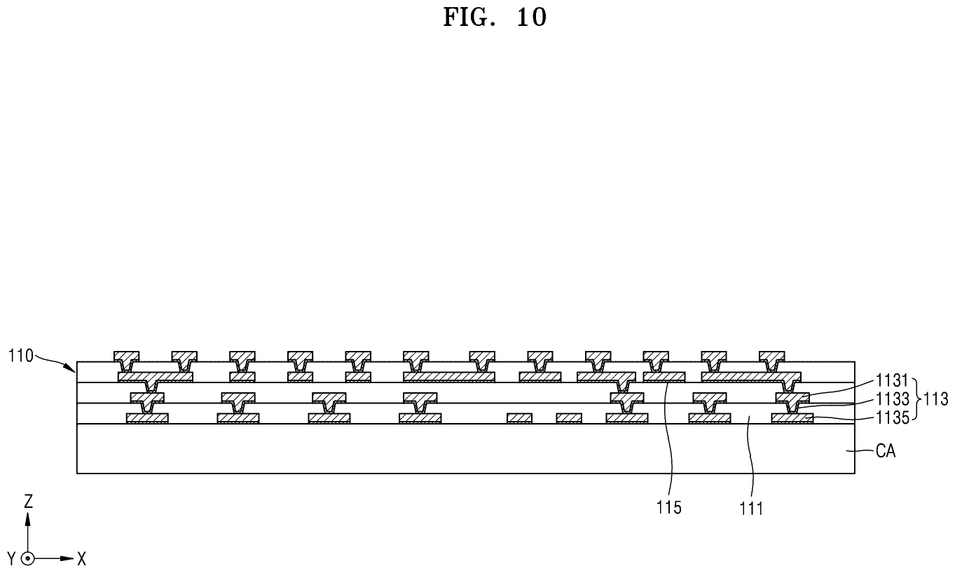

FIGS. 10 to 17 are cross-sectional views of a method of manufacturing a semiconductor package, according to an example embodiment. Hereinafter, the method of manufacturing the semiconductor package described with reference to FIGS. 1 to 3 is described with reference to FIGS. 10 to 17.

Referring to FIG. 10, a first redistribution structure 110 may be formed on a carrier substrate CA. The first redistribution structure 110 may include a plurality of first redistribution insulating layers 111 sequentially stacked on the carrier substrate CA and a first conductive redistribution pattern 113 insulated by the plurality of first redistribution insulating layers 111. The first conductive redistribution pattern 113 may include external connection pads 1135 extending along a top surface of the carrier substrate CA, first conductive layers 1131 extending along top surfaces of the plurality of first redistribution insulating layers 111, and first conductive via patterns 1133 extending to pass through any one of the plurality of first redistribution insulating layers 111.

To form the first redistribution structure 110, to begin with, the external connection pads 1135 may be formed on the carrier substrate CA. The external connection pads 1135 may be formed using a plating process. For example, a seed metal layer 115 may be formed on the carrier substrate CA, and then the external connection pads 1135 may be formed by performing a plating process using the seed metal layer 115. After the external connection pads 1135 are formed, a first operation of forming the first redistribution insulating layers 111 having via holes to cover the external connection pads 1135 and a second operation of forming a plurality of first conductive via patterns 1133 filling the via holes of the first redistribution insulating layers 111 and forming the first conductive layers 1131 extending along a top surface of the first redistribution insulating layers 111 may be performed. The second operation of forming the plurality of first conductive via patterns 1133 and the first conductive layer 1131 may include a plating process using the seed metal layer 115. Subsequently, the first operation of forming the first redistribution insulating layers 111 and the second operation of forming the plurality of first conductive via patterns 1133 and the first conductive layer 1131 may be repeated several times to form the first redistribution structure 110 having a multilayered wiring structure.

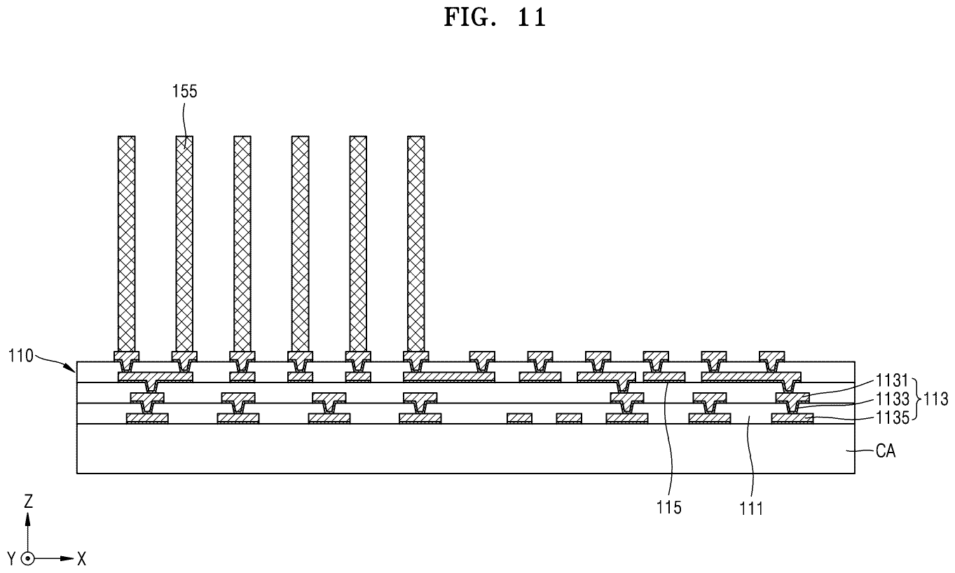

Referring to FIG. 11, vertical connection conductors 155 may be formed on the first redistribution structure 110. The vertical connection conductors 155 may be formed using a plating process.

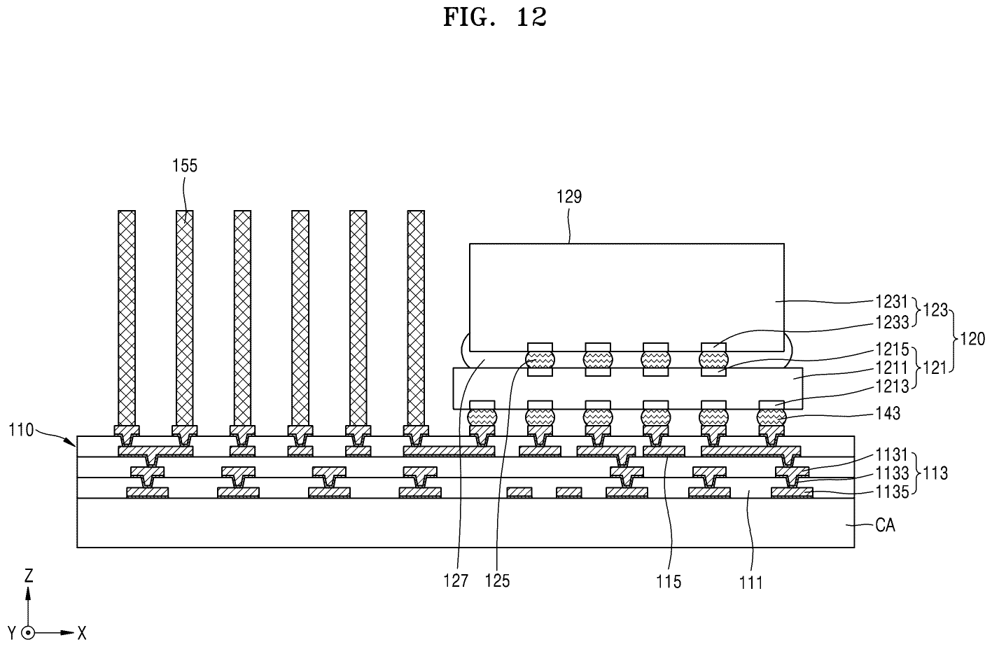

Referring to FIG. 12, a first lower semiconductor device 120 may be mounted on the first redistribution structure 110. The first lower semiconductor device 120 may be mounted on the first redistribution structure 110 by using the first chip connection bumps 143.

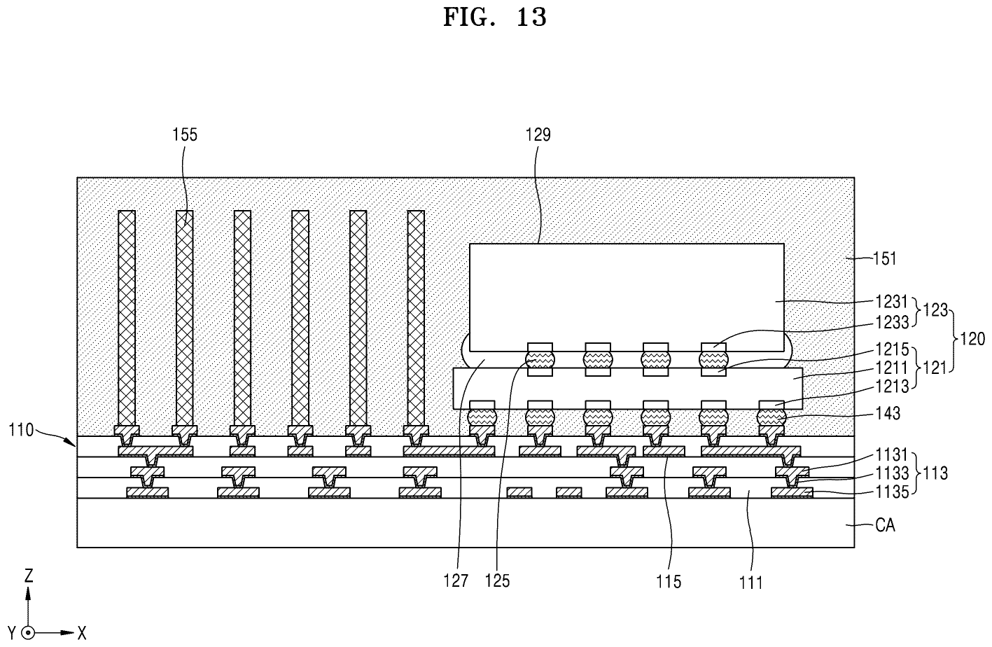

Referring to FIG. 13, a molding layer 151 covering the first lower semiconductor device 120 and the vertical connection conductors 155 may be formed on the first redistribution structure 110. The formation of the molding layer 151 may include supplying a molding material onto the carrier substrate CA and curing the molding material.

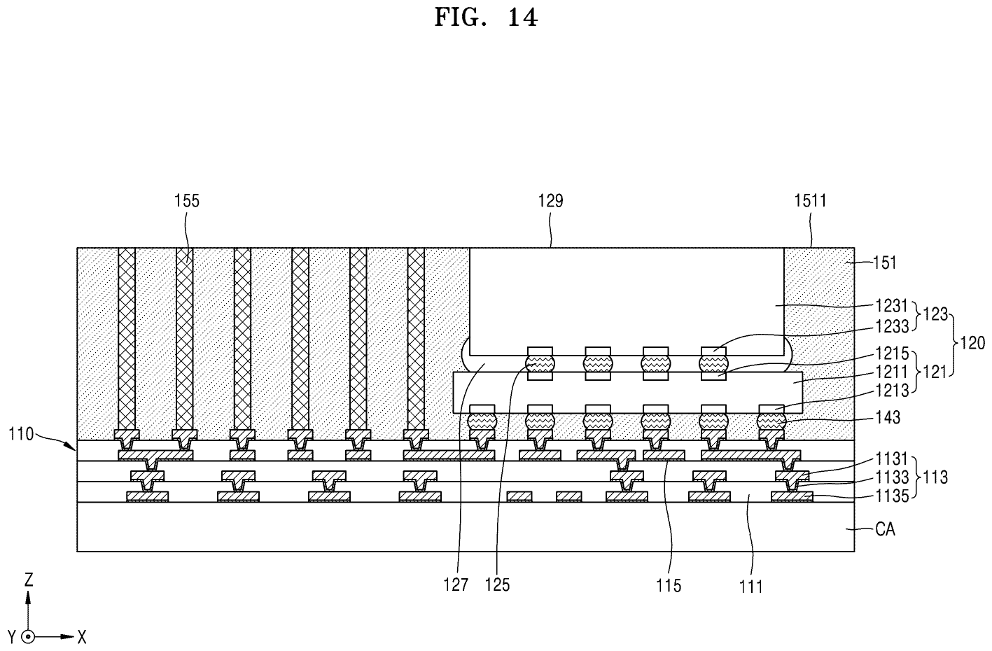

Referring to FIG. 14, a portion of the molding layer 151 may be removed to expose the first lower semiconductor device 120 and the vertical connection conductors 155. To remove the portion of the molding layer 151, a chemical mechanical polishing (CMP) process and/or a grinding process may be performed. For example, a portion of the molding layer 151, a portion of each of the vertical connection conductors 155, and a portion of the first lower semiconductor device 120 may be removed by using a polishing process. In some example embodiments, as a result of the polishing process, a polished top surface 1511 of the molding layer 151 may be coplanar with a top surface 129 of the first lower semiconductor device 120 and a top surface of each of the vertical connection conductors 155.

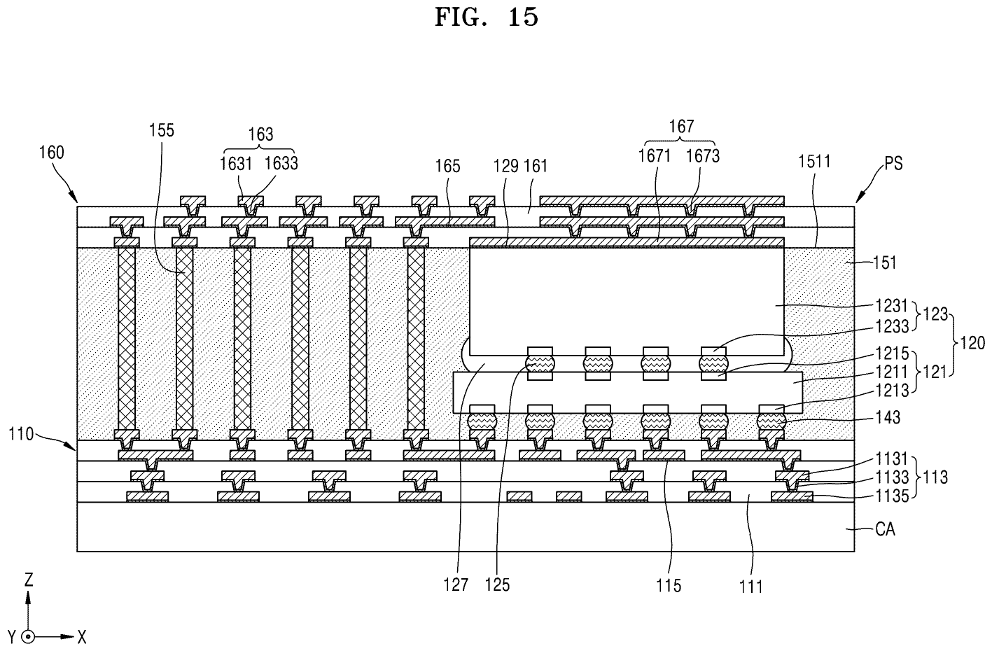

Referring to FIG. 15, a second redistribution structure 160 may be formed on the top surface 1511 of the molding layer 151 and the top surface 129 of the first lower semiconductor device 120. The second redistribution structure 160 may include a plurality of second redistribution insulating layers 161, a second conductive redistribution pattern 163, and a third conductive redistribution pattern 167. The plurality of second redistribution insulating layers 161 may be sequentially stacked on the top surface 1511 of the molding layer 151 and the top surface 129 of the first lower semiconductor device 120. The second conductive redistribution pattern 163 and the third conductive redistribution pattern 167 may be insulated by the plurality of second redistribution insulating layers 161.

The second conductive redistribution pattern 163 may include second conductive layers 1631 extending along the top surface of the plurality of second redistribution insulating layers 161 and second conductive via pattern 1633 extending to pass through any one of the plurality of second redistribution insulating layers 161. The third conductive redistribution pattern 167 may include third conductive layers 1671 extending along the top surface of the plurality of second redistribution insulating layers 161 and third conductive via pattern 1673 extending to pass through any one of the plurality of second redistribution insulating layers 161.

To form the second redistribution structure 160, a lowermost one of second conductive layers 1631 may be formed to be connected to the vertical connection conductors 155. For example, a seed metal layer 165 may be formed on the vertical connection conductors 155, and thus, the lowermost one of the second conductive layers 1631 and a third conductive layer 1671 may be formed by performing a plating process using the seed metal layer 115. Next, a first operation of forming the second redistribution insulating layer 161 having via holes to cover the lowermost one of the second conductive layers 1631 and the third conductive layer 1671 and a second operation of forming a second conductive via pattern 1633 and a third conductive via pattern 1673 to fill the via holes of the insulating film may be performed. In the second operation, the second conductive layers 1631 and the third conductive layer 1671, which extend along a top surface of second redistribution insulating layer 161, may be further formed. The second operation of forming the second conductive via pattern 1633, the third conductive via pattern 1673, the second conductive layer 1631, and the third conductive layer 1671 may include a plating process using the seed metal layer 165. Subsequently, the first operation of forming the second redistribution insulating layer 161 and the second operation of forming the second conductive via pattern 1633, the third conductive via pattern 1673, the second conductive layer 1631, and the third conductive layer 1671 may be repeated several times to form the second redistribution structure 160 having a multilayered wiring structure.

The first redistribution structure 110, the first lower semiconductor device 120, the vertical connection conductors 155, the molding layer 151, and the second redistribution structure 160 may form a package structure PS of a panel type.

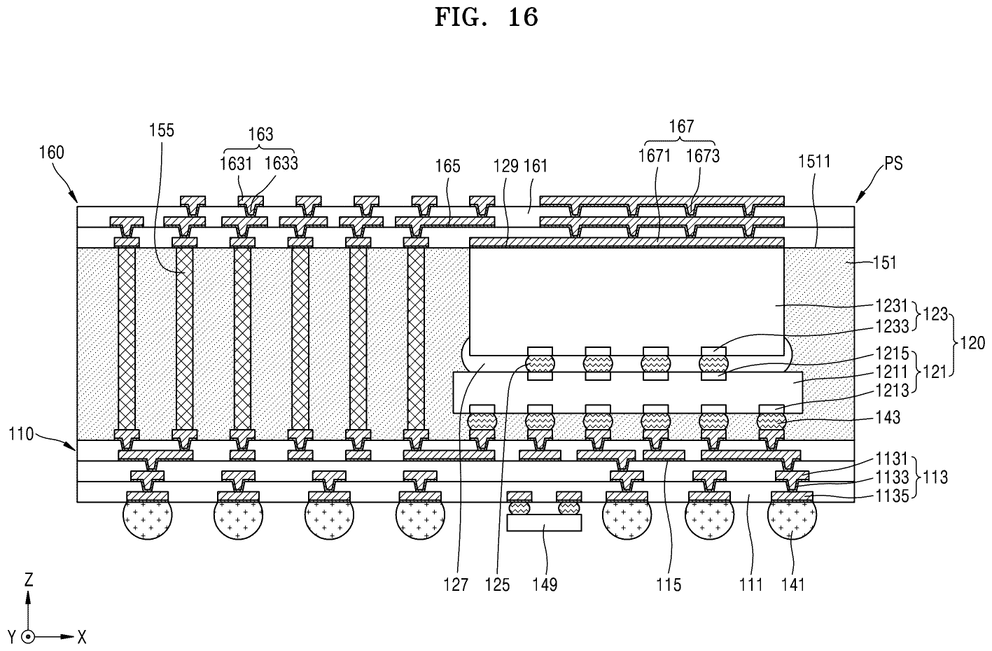

Referring to FIG. 16, the carrier substrate (refer to CA in FIG. 15) may be removed from the first redistribution structure 110. Thereafter, external terminals 141 and a passive component 149 may be adhered to a lower side of the first redistribution structure 110.

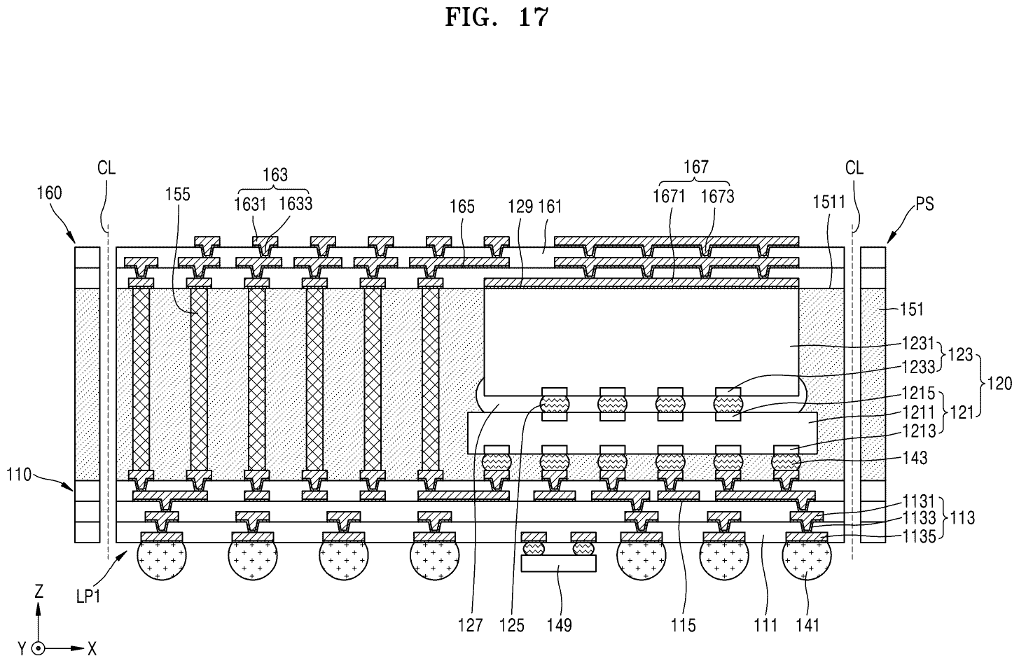

Referring to FIG. 17, the package structure PS may be cut along a cutting line CL. By performing a cutting process on the package structure PS, the package structure PS may be separated into a plurality of lower packages LP1.

Next, referring to FIGS. 1 to 3, an upper package UP and a heat-dissipation plate 185 may be adhered onto the lower package LP1 that is separated as an individual unit. An upper semiconductor device 181 that constitutes the upper package UP may be mounted on the second redistribution structure 160 and overlap a portion of the first lower semiconductor device 120 in a vertical direction (Z direction), and the heat-dissipation plate 185 may be adhered onto the third conductive redistribution pattern 167 through a thermally conductive adhesive layer 187.

While the inventive concepts have been particularly shown and described with reference to some example embodiments thereof, it will be understood that various changes in form and details may be made therein without departing from the spirit and scope of the following claims.

What is claimed is:

1. A semiconductor package comprising:
a redistribution structure comprising a redistribution insulating layer and a redistribution pattern;
a first semiconductor device on the redistribution structure;
vertical connection conductors on the redistribution structure and apart from the first semiconductor device in a horizontal direction;
a second semiconductor device on the vertical connection conductors; and
a heat-dissipation plate on the first semiconductor device,
wherein the heat-dissipation plate comprises a main body and a plurality of protrusions protruding from the main body in the horizontal direction.

2. The semiconductor package of claim 1, wherein the heat-dissipation plate further comprises a connection apart from the main body in the horizontal direction, the connection being configured to connect the plurality of protrusions to each other.

3. The semiconductor package of claim 2, wherein, when viewed in a horizontal cross-section, a center of the heat-dissipation plate is apart from a center of the second semiconductor device.

4. The semiconductor package of claim 1, further comprising:
a heat-dissipation pad structure between the heat-dissipation plate and the first semiconductor device.

5. The semiconductor package of claim 4, wherein the heat-dissipation pad structure is in contact with a top surface of the first semiconductor device.

6. The semiconductor package of claim 1, further comprising:
a third semiconductor device apart from the first semiconductor device in the horizontal direction, the third semiconductor device being on the redistribution structure,
wherein the third semiconductor device overlaps the second semiconductor device in a vertical direction.

7. The semiconductor package of claim 1, wherein the second semiconductor device overlaps at least a portion of the first semiconductor device in a vertical direction.

8. A semiconductor package comprising:
a first redistribution structure comprising a first redistribution insulating layer and a first redistribution pattern;
a first semiconductor device on the first redistribution structure;
a molding layer surrounding the first semiconductor device on the first redistribution structure;
a second redistribution structure on the molding layer and the first semiconductor device, the second redistribution structure comprising a second redistribution insulating layer and a second redistribution pattern;
vertical connection conductors in the molding layer, the vertical connection conductors being apart from the first semiconductor device in a horizontal direction, the vertical connection conductors being between the first redistribution structure and the second redistribution structure;
a second semiconductor device on the second redistribution structure; and
a heat-dissipation plate apart from the second semiconductor device, the heat-dissipation plate being on the second redistribution structure,
wherein the heat-dissipation plate comprises a main body and a plurality of protrusions protruding from the main body in the horizontal direction.

9. The semiconductor package of claim 8, wherein, when viewed in a horizontal cross-section, the heat-dissipation plate has a U shape.

10. The semiconductor package of claim 8, wherein, when viewed in a horizontal cross-section, the heat-dissipation plate has a shape of a tetragonal ring.

11. The semiconductor package of claim 10, wherein, when viewed in a horizontal cross-section, the second semiconductor device is inside the tetragonal ring.

12. The semiconductor package of claim 8, wherein the second redistribution structure comprises a through hole, and the second semiconductor device is inside the through hole.

13. The semiconductor package of claim 8, wherein at least 70% of the first semiconductor device overlaps the heat-dissipation plate in a vertical direction.

14. The semiconductor package of claim 8, wherein a top surface of the molding layer is at a same vertical level as a top surface of the second semiconductor device.

15. The semiconductor package of claim 8, wherein, when viewed in a horizontal cross-section, at least two of a plurality of sides of the second semiconductor device face the heat-dissipation plate.

16. The semiconductor package of claim 8, wherein the first semiconductor device comprises a logic chip, and the second semiconductor device comprises a memory chip.

17. A semiconductor package comprising:
a first redistribution structure comprising a first redistribution insulating layer and a first redistribution pattern;
a first semiconductor device on the first redistribution structure;
a molding layer surrounding the first semiconductor device on the first redistribution structure;
a second redistribution structure on the molding layer and the first semiconductor device, the second redistribution structure comprising a second redistribution insulating layer and a second redistribution pattern;
vertical connection conductors in the molding layer, the vertical connection conductors being apart from the first semiconductor device in a horizontal direction, the vertical connection conductors being between the first redistribution structure and the second redistribution structure;
a second semiconductor device on the second redistribution structure; and
a heat-dissipation plate apart from the second semiconductor device, the heat-dissipation plate being on the second redistribution structure,
wherein the first redistribution pattern comprises a first conductive layer and a first via pattern,
the second redistribution pattern comprises a second conductive layer and a second via pattern,
the heat-dissipation plate comprises a main body and a plurality of protrusions protruding from the main body in the horizontal direction,
a first side of the main body and one side of a first protrusion form a straight line in one horizontal direction, and
a second side of the main body and one side of a second protrusion form a straight line in the one horizontal direction.

18. The semiconductor package of claim 17, wherein
the second redistribution structure further comprises a third redistribution pattern apart from the second redistribution pattern in the horizontal direction,
the third redistribution pattern comprises a third conductive layer and a third via pattern.

19. The semiconductor package of claim 18, wherein the third conductive layer has a plate form.

20. The semiconductor package of claim 18, wherein the heat-dissipation plate is on the third conductive layer.
